(19) United States
(12) Patent Application Publication
(10) Pub. No.: US 2026/0336835 A1
(43) Pub. Date: Oct. 29, 2026

(54) MAGNETOHYDRODYNAMICALLY PUMPED LIQUID METAL LOOPS FOR SPACECRAFT THERMAL CONTROL

(71) Applicant: GEORGIA TECH RESEARCH CORPORATION, Atlanta, GA (US)

(72) Inventor: Alvaro ROMERO-CALVO, Atlanta, GA (US)

(21) Appl. No.: 19/487,588

(22) PCT Filed: May 27, 2024
(86) PCT No.: PCT/US2024/031202

§ 371 Date: Nov. 25, 2025

Related U.S. Application Data
(60) Provisional application No. 63/504,558, filed on May 26, 2023.

(51) Int. Cl. B64G 1/50; H02K 44/06

(52) U.S. Cl. CPC B64G 1/50; H02K 44/06

(57) ABSTRACT

A system includes a heat-transfer conduit forming a circulating loop with a liquid metal. Heat exchangers are coupled to either end of the circulating loop to transfer heat to and from the liquid metal. A magnetohydrodynamic pump assembly is coupled to the conduit and comprising (i) an electrode configured to generate an electric current density in a first direction, (ii) a magnet configured to generate a magnetic flux density in a second direction perpendicular to the first direction. A resulting Lorentz force between the electrode and the magnet induces motion of the liquid metal in a third direction parallel to the longitudinal axis of the conduit loop. A controller is coupled to the magnetohydrodynamic pump assembly and configured to adjust an electric current applied to the electrode to vary the intensity of the electric current density, which varies a flow rate of the liquid metal.

### CROSS-REFERENCE TO RELATED APPLICATIONS

This application claims priority to U.S. Provisional Patent Application No. 63/504,558, filed May 26, 2023, which is incorporated herein by reference in its entirety.

### BACKGROUND

Recent improvements in solar power generation and energy storage have opened the door for high-power spacecraft platforms with mission-enabling advances in electric propulsion, imaging payloads, or communications. As the power density grows, heat rejection and transport become increasingly important.

Body-mounted radiators are constrained by the limited spacecraft surface, making deployable alternatives imperative for future missions. With them comes the need for high-power heat transport. Thermal straps are inefficient for highly demanding applications, while heat pipes reach their limit for heat fluxes beyond 16 W/cm². Alternatively, mechanically pumped loops have been considered for high-power density systems, tight temperature control, distributed heat sources, or confined access. These qualitative advantages are usually balanced against the additional mass and reduced reliability associated with active pumps, which are the single most crucial component of the loop. Redundant architectures are therefore required at the expense of mass.

There are, nevertheless, benefits to improving thermal control for satellites.

### SUMMARY

An exemplary active thermal control device and method are disclosed that employ a heat transfer conduit (e.g., a liquid metal loop) propelled by a magnetohydrodynamic (MHD) pump. The magnetohydrodynamic pump can induce liquid motion by exploiting the Lorentz volume force J×B imposed on a single-phase liquid metal in which J as the current density generated between two electrodes immersed in the liquid and B the magnetic flux density applied by permanent neodymium magnets. Analytical estimations indicate that the device is able to satisfy the need for miniaturized and low-power active spacecraft thermal systems (e.g., small satellite systems) by reducing the mass required per unit of transferred power by up to ~60-80% with respect to state of the art.

This value applies to an LEO reference mission where a 60 W heat flux needs to be dissipated from a 60 °C payload using a 1200 cm² deployable radiator. The absence of moving parts and the high electric conductivity of the liquid result in enhanced reliability and minimum power consumption. Furthermore, the near-zero vapor pressure of the liquid metal precludes leaks and minimizes the pressure difference between the loop and the external environment, reducing the mass of the pipes and facilitating the use of non-metallic lightweight materials. With thermal conductivity values two orders of magnitude above standard refrigerants, the volume and mass of heat exchangers are reduced proportionally.

In other embodiments, the exemplary active thermal control device and method may be employed for high-power electronics, hypersonic reentry vehicles, and larger spacecraft.

According to one aspect of the disclosure, a system is disclosed, the system including: a heat transfer conduit, a first heat exchanger, a second heat exchanger, a magnetohydrodynamic pump assembly, and a controller. The heat-transfer conduit has a first end and a second end opposite the first end that forms a circulating loop, the conduit defining a flow channel including a liquid metal. The first heat exchanger is provided to couple to a thermal load (e.g., one or more devices) disposed on the first end of the conduit loop and configured to transfer heat from a connected thermal load into the liquid metal of the conduit. The second heat exchanger is provided to couple to a thermal sink, the second heat exchanger being disposed on the second end of the conduit and configured to transfer heat from the liquid metal to the thermal sink. The magnetohydrodynamic pump assembly is coupled to a portion of the conduit. The magnetohydrodynamic pump assembly includes (i) at least one electrode configured to generate an electric current density in a first direction perpendicular to a longitudinal axis of the portion of the conduit loop, (ii) at least one magnet configured to generate a magnetic flux density in a second direction perpendicular to both the first direction and the longitudinal axis of the portion of the conduit. The controller is coupled to the magnetohydrodynamic pump assembly and configured to adjust an electric current applied to the at least one electrode to vary the intensity of the electric current density in the first direction, which varies a flow rate of the liquid metal wherein a resulting Lorentz force between the at least one electrode and the at least one magnet induces motion of the liquid metal in a third direction parallel to the longitudinal axis of the portion of the conduit loop.

In some implementations, the at least one electrode includes a first electrode on a first side of the conduit loop and a second electrode on a second side of the conduit loop opposite of the first side, the first and second electrodes being separated by a first distance. In some implementations, the first and second electrode are in contact with the liquid metal.

In some implementations, the at least one magnet includes a first set of magnets on a third side of the conduit loop and a second set of magnets on a fourth side of the conduit loop opposite of the third side, the first and second set of magnets being separated by a second distance. In some implementations, the first set of magnets includes 3 neodymium magnets arranged in series in the magnetohydrodynamic pump along the third side of the conduit loop.

In some implementations, the at least one magnet is a neodymium magnet (e.g., a 4.76 mm cubic nickel-plated N52 neodymium magnet). In some implementations, the liquid metal is one of gallium, Galinstan, mercury, or NaK-77.

In some implementations, the system further includes a controller operatively coupled to the magnetohydrodynamic pump, the controller being configured to operate the magnetohydrodynamic pump to increase or decrease a flowrate of the liquid metal therethrough. In some implementations, the controller is configured to operate the magnetohydrodynamic pump based on a Lorentz volume force or static pressure of the liquid metal.

In some implementations, the magnetohydrodynamic pump is configured to transfer a pre-defined heat flux from a subsystem of a satellite to a deployable radiator.

In some implementations, the system further includes a power supply, wherein the electric current density generated in the at least on electrode is a DC current source from the power supply.

In some implementations, the electric current density generated in the at least one electrode is a DC current source generated by the controller.

In some implementations, the magnetohydrodynamic pump is a first magnetohydrodynamic pump coupled to a first portion of the conduit loop, the system further including a second magnetohydrodynamic pump coupled to a second portion of the conduit loop, each of the first and second magnetohydrodynamic pumps configured to apply a Lorentz force to induce motion of the liquid metal.

According to another aspect of the disclosure, a satellite or spacecraft system is disclosed, the system including a heat transfer conduit, a first heat exchanger, a second heat exchanger, a magnetohydrodynamic pump assembly, and a controller. The heat-transfer conduit has a first end and a second end opposite the first end that forms a circulating loop, the conduit defining a flow channel including a liquid metal. The first heat exchanger is provided to couple to a thermal load (e.g., one or more devices) disposed on the first end of the conduit loop and configured to transfer heat from a connected thermal load into the liquid metal of the conduit. The second heat exchanger is provided to couple to a thermal sink, the second heat exchanger being disposed on the second end of the conduit and configured to transfer heat from the liquid metal to the thermal sink. The magnetohydrodynamic pump assembly is coupled to a portion of the conduit. The magnetohydrodynamic pump assembly including (i) at least one electrode configured to generate an electric current density in a first direction perpendicular to a longitudinal axis of the portion of the conduit loop, (ii) at least one magnet configured to generate a magnetic flux density in a second direction perpendicular to both the first direction and the longitudinal axis of the portion of the conduit. The controller is coupled to the magnetohydrodynamic pump assembly and configured to adjust an electric current applied to the at least one electrode to vary the intensity of the electric current density in the first direction, which varies a flow rate of the liquid metal wherein a resulting Lorentz force between the at least one electrode and the at least one magnet induces motion of the liquid metal in a third direction parallel to the longitudinal axis of the portion of the conduit loop.

According to another aspect of the disclosure, a method of transferring heat is disclosed, the method including: providing a heat-transfer conduit having a first end and a second end opposite the first end that forms a circulating loop, the conduit defining a flow channel including a liquid metal, wherein a first heat exchanger to couple to a thermal load is disposed on the first end of the conduit loop and configured to transfer heat from a connected thermal load into the liquid metal of the conduit, wherein a second heat exchanger to couple to a thermal sink is disposed on the second end of the conduit and configured to transfer heat from the liquid metal to the thermal sink; providing a magnetohydrodynamic pump assembly coupled to a portion of the conduit, the magnetohydrodynamic pump assembly including at least one electrode on a first side of the portion of the conduit and at least one magnet on a second side of the portion of the conduit; applying a current to the at least one electrode to generate an electric current density in a first direction perpendicular to the longitudinal axis of the conduit; generating a magnetic flux density in a second direction perpendicular to both the first direction and the longitudinal axis of the conduit; inducing motion of the liquid metal in a longitudinal direction along the conduit via the resulting Lorentz force generated by the electric current density and the magnetic flux density.

In some implementations, the method further includes providing a controller coupled to the magnetohydrodynamic pump assembly; and adjusting an electric current applied to the at least one electrode to vary the intensity of the electric current density in the first direction.

In some implementations, adjusting the electric current applied to the at least one electrode adjusts the flow rate of the liquid metal through the conduit.

In some implementations, the method further includes providing a power supply coupled to the at least one electrode and the controller; and generating a DC current to the at least one electrode to generate the electric current density.

In some implementations, the thermal load is a heat-generating device of a device (e.g., a small satellite), and the thermal sink is a radiator (e.g., a deployable radiator) configured to dissipate the heat into an external environment.

In some implementations, the thermal load includes a plurality of heat-generating devices of a satellite or spacecraft system, wherein the thermal sink is a deployable radiator of the satellite or spacecraft system, the magnetohydrodynamic pump assembly being powered by a power supply of the satellite or spacecraft system (e.g., solar power).

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

FIG. 1 shows a system (e.g., a satellite system) including a magnetohydrodynamic (MHD) pump, according to one implementation.

FIGS. 2A and 2B show an image of a prototypical magnetohydrodynamic pump (MHD), according to one implementation.

FIG. 3 shows a diagram of an MHD pump configured as a brick, according to one implementation.

FIG. 4 shows a test setup for an evaluation of the exemplary system of FIG. 1 employed in a study.

FIGS. 5A and 5B show the heat transferred by each of the liquids listed in Table 1 as a function of the overall mass of the loop, according to one implementation.

FIG. 6A shows a graph of simulation data showing the magnetic flux (B) field generated by a pair of opposing block magnets, according to one implementation.

FIG. 6B shows a graph of simulation data showing the current density field (J) generated by a pair of opposing electrodes, according to one implementation.

FIG. 7A shows a diagram of an experimental setup, including a pump attached between two cylindrical tanks partially filled with gallium, according to one implementation.

FIG. 7B shows a diagram of an experimental setup, including a single MHD pump connected to a magnetic flow rate sensor, according to one implementation.

FIGS. 8A and 8B show graphs of the analytical prediction of the heat transferred by an MHD cooling loop containing each of the liquids listed in Table 1 as well as a copper heat strap as a function of the overall mass of the device, according to one implementation.

FIGS. 9A and 9B show graphs displaying the contours of the pump flow coefficient and static output pressure developed in the analytical study, according to one implementation.

FIGS. 10A and 10B show graphs displaying the pressure output by the system in a steady, non-flowing configuration as compared to the analytical prediction, according to one implementation.

FIG. 10C shows a graph of the measured flow rate in a 30 cm loop as compared to analytical predictions, according to one implementation.

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

### DETAILED DESCRIPTION

Referring generally to the figures, a heat exchange system using a magnetohydrodynamic (MHD) pump is shown, according to various implementations.

### Example System

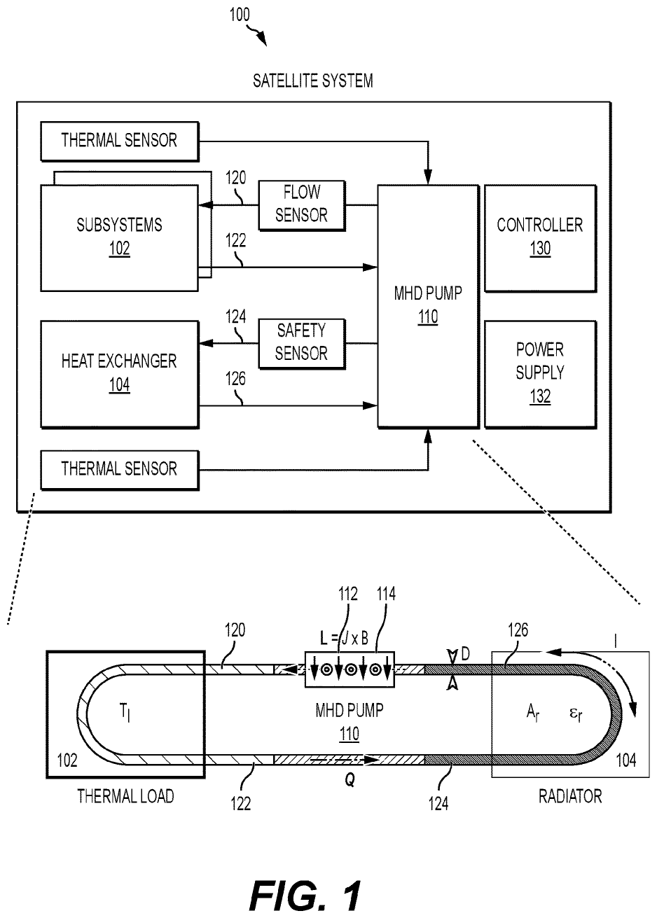

FIG. 1 shows a system 100 (e.g., a satellite system or other spacecraft system operable in low-earth orbit or other low-gravity conditions), according to one implementation of this disclosure. The system 100 includes one or more subsystems 102 of the satellite system. For example, the subsystems 102 may include a processor, a power supply unit, a communication system, payload instruments, or propulsion systems of the satellite. Any one of these elements, or others, of the satellite may generate heat or thermal load. Excess heat in the system 100 must be expelled (e.g., via radiation) to avoid the risk of overheating of the subsystems 102 that may lead to failure.

The disclosed system 100 can dissipate the heat from the thermal load (e.g., the subsystems 102) via a heat exchanger 104 in thermal communication with the subsystems 102. The heat exchanger 104 is a thermal sink of the system 100. The heat exchanger 104 may be a radiator or a deployable radiator configured to dissipate heat into an external environment (e.g., space).

This system 100 includes a magnetohydrodynamic (MHD) pump assembly 110. The MHD pump assembly 110 is coupled to a series of heat-transfer conduits. For example, the MHD pump assembly 110 is coupled to a first end of the heat-transfer conduits, including a first heat-transfer conduit 120 extending from the MHD pump assembly 110 to the subsystems 102 and a second heat-transfer conduit 122 extending from the subsystems 102 to the MHD pump assembly 110. The MHD pump assembly 110 is also coupled to a second end of the heat transfer conduits that is opposite the first end of the heat transfer conduits. The second end of the heat transfer conduits includes a third heat transfer conduit 124 extending from the MHD pump assembly 110 to the heat exchanger 104 and a fourth heat transfer conduit 126 extending from the heat exchanger 104 to the MHD pump assembly 110.

Optionally, one or more flow sensors and/or safety sensors are disposed on the heat transfer conduits 122-126. For example, the flow sensors may monitor the flow rate of the liquid metal through the flow channel of the fluid conduit. In some implementations, a controller is coupled to the flow sensor, forming a feedback loop to adjust and control the flow rate of the liquid metal. In some implementations, a safety valve is included and configured to halt the flow of liquid metal through the flow channel (e.g., in an emergency situation or when heat dissipation operations are suspended).

Optionally, thermal sensors are included in the system 100 coupled to one or more of the subsystems 102, the heat exchanger 104, the MHD pump assembly 110, or the heat transfer conduit therebetween. The thermal sensors may measure a temperature of the components of the system and/or the liquid metal. In some implementations, a controller is coupled to the thermal sensors, forming a feedback loop to adjust and control the flow rate of the liquid metal and/or the rate of heat dissipation/generation.

Together, the first heat transfer conduit 120, the second heat transfer conduit 122, the third heat transfer conduit 124, and the fourth heat transfer conduit 126 form the heat transfer conduit assembly of the system 100. The heat transfer conduit assembly forms a circulating loop extending from the first end to the second end (i.e., from the subsystems 102, through the MHD pump assembly 110, to the heat exchanger 104, and back again). A simplified version of the circulating loop is shown in the bottom/expanded panel of FIG. 1.

The circulating loop of a heat transfer conduit defines a flow channel within which a liquid metal flows. The liquid metal acts as the heat transfer medium by which heat from the thermal load (e.g., the subsystems 102) is moved to and dissipated via the thermal sink (e.g., the heat exchanger 104). The liquid metal may be one of gallium, Galinstan, mercury, or NaK-77. In other implementations, the liquid metal is any metal having a high specific heat transfer capacity (W/g) that is liquid in the steady state environment (e.g., in low earth orbit (LEO)). In some embodiments, the coolant may be ionic liquids.

The MHD pump assembly 110 is coupled to a portion of the heat-transfer conduit circulating loop. The MHD pump assembly 110 includes at least one electrode 112 (e.g., a plurality of electrodes 112). For example, the electrodes 112 may be disposed on opposite sides of the flow channel of the heat transfer conduit, separated by a distance. In some implementations, the electrodes 112 directly contact the liquid metal in the flow channel.

The electrodes 112 controllably generate an electric current density in a first direction. The electric current density (denoted “J”) is shown in the diagram of FIG. 1 as pointing down the page, perpendicular to a longitudinal axis of the portion of the heat-transfer conduit.

The electric current density J is controllable (e.g., on/off and level of intensity) based on the applied voltage. For example, a controller 130 of the system 100 is coupled to the MHD pump assembly 110 and the electrodes 112 therein. The controller 130 is configured to adjust the electric current applied to the electrodes 112 to vary the intensity of the electric current density J (e.g., via a DC current source). As explained below, this adjustment also varies the flow rate of liquid metal through the heat transfer conduit's circulating loop. A power supply 132 (e.g., a battery) may be coupled to the controller 130 and/or the MHD pump assembly 110 to provide the required power for generating the applied voltage.

The MHD pump assembly 110 further includes at least one magnet 114 (e.g., a neodymium magnet or magnet array). For example, a set of magnets 114 may be disposed on either side of the flow channel of the heat transfer conduit opposite from each other. The sides on which the magnets 114 are disposed are perpendicular to the sides on which the electrodes 112 are disposed.

The magnet 114 generates a magnetic flux density (denoted “B”) in a second direction that is perpendicular to both the first direction and the longitudinal axis of the portion of the heat-transfer conduit. As shown in FIG. 1, the magnetic flux density B is shown extending out of the page (represented by the dot-and-circle symbol inside the MHD pump assembly 110). The magnetic flux density B may be fixed based on the type and number of magnets used in the system 100. However, in other implementations, the magnetic flux density B may be varied (e.g., via an applied voltage or a changed geometry of the magnetohydrodynamic pump assembly).

The perpendicular electric current density J and the magnetic flux density B create a resulting Lorentz force L (L=J×B). The Lorentz force L induces motion of the liquid metal within the flow channel of the heat-transfer conduit. Specifically, the Lorentz force L induces motion in a third direction that is perpendicular to both the first direction of the electric current density J and the second direction of the magnetic flux density B. The third direction of the Lorentz force L is parallel to the longitudinal direction of the portion of the heat transfer conduit coupled to the MHD pump assembly 110. Thus, the Lorentz force L creates a pressure differential in the liquid metal and urges the liquid metal along the heat transfer conduit.

In use, excess heat generated from the subsystems 102 forms a thermal load on one side of the circulating loop of the heat transfer conduit. The subsystems 102 are coupled to the heat transfer conduit (e.g., via a heat exchanger). The controller 130 applies a voltage to the electrodes 112 of the MHD pump assembly 110 (e.g., in response to a signal detecting increased thermal load or temperature of the system 100). The applied voltage generates an electric current density J adjacent to the magnetic flux density B already present from the magnet 114 of the MHD pump assembly 110.

A Lorentz force L is generated by the cross product of the electric current density J and the magnetic flux density B, creating a pressure differential in the liquid metal in the flow channel defined by the circulating loop of the heat-transfer conduit. Thus, a portion of the liquid metal flows from the portion of the heat-transfer conduit adjacent to the MHD pump assembly 110 and towards the subsystems 102 along the first heat-transfer conduit 120.

The liquid metal flowing from the first heat transfer conduit 120 enters the subsystems 102 (e.g., heat exchanger coupled to the subsystems 102). Heat is then transferred from the subsystems 102 to the liquid metal, effectively cooling the subsystems 102. The heated liquid metal then flows along the second heat transfer conduit 122 and towards the heat exchanger 104.

In some implementations, the MHD pump assembly 110 includes a second MHD pump assembly, similar to the first MHD pump assembly 110, but oriented in the opposite direction (e.g., to urge liquid metal from the second heat transfer conduit 122 towards the third heat transfer conduit 124). Such a system may increase the pressure differential and, thus, the flow rate of liquid metal through the heat transfer conduit.

The heated liquid metal flows along the third heat transfer conduit 124 and into the heat exchanger 104. Heat is then transferred from the liquid metal to the heat exchanger 104 and then radiated to the external environment (e.g., via an expandable radiator coupled to a side of the satellite system 100). The now cooled liquid metal flows back towards the MHD pump assembly 110 along the fourth heat transfer conduit 126, and the cycle starts over again.

In some implementations, more than one magnetohydrodynamic (MHD) pump assemblies and/or more than one circulating loop is included in the system. For example, two circulating loops of the heat transfer conduit may be included, each with its own magnetohydrodynamic (MHD) pump assembly. The two circulating loops may have opposing flow directions (e.g., clockwise and counter-clockwise) to reduce gyroscopic and other control effects on the satellite system.

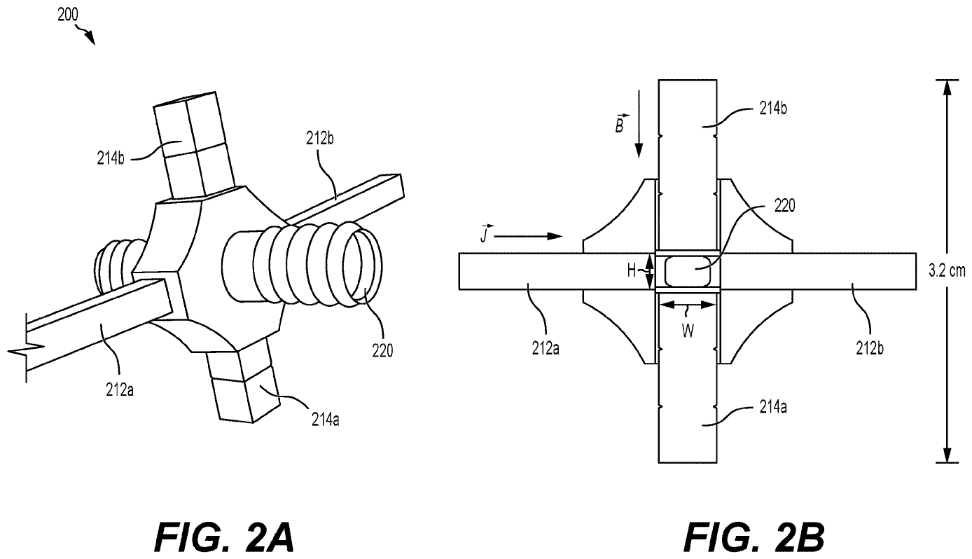

FIG. 2A and FIG. 2B show a prototypical magnetohydrodynamic (MHD) pump 200, according to one implementation. The MHD pump 200 includes a stack of magnets, including a first magnet array 214a and a second magnet array 214b, each arranged on opposite sides of the flow channel of the heat transfer conduit 220. The magnets are 4.76 mm cubic nickel-plated permanent neodymium (N52) magnets. Three magnets are included in each magnet array 214a, 214b. In other embodiments, the magnetic field can be generated in the noted direction via electromagnets or permanent magnets with a ferric core. In other embodiments, other numbers of magnetic field sources can be used, e.g., 3, 4, 5, 6, 7, 8, etc.

The MHD pump further includes an electrode assembly including a first electrode 212a and a second electrode 212b. The electrodes are square bars of copper oriented axially towards the heat transfer conduit 220. The inner edges of each of the first electrode 212a and the second electrode 212b define the boundaries of the flow channel and, in use, directly contact the liquid metal.

As shown, the flow channel of the heat transfer conduit 220 has a height H and a width W. The height H is the distance between the first magnet array 214a and the second magnet array 214b across the flow channel (or the height of the wetted pump cross-section). The height H shown is 2.5 mm, e.g., for a small cooling system. However, in other implementations, the height H between the magnets scaled for larger systems.

The width W is the distance between the first electrode 212a and the second electrode 212b across the flow channel (or the width of the wetted pump cross-section). The width W shown is 4.0 mm. However, in other implementations, the width W between the electrodes may scaled for larger system.

### Experimental Testing and Results

### #1—Magnetohydrodynamically Pumped Liquid Metal Loops for SmallSat Thermal Control

The closed-loop liquid metal heat pipe shown in the lower panel of FIG. 1 is considered. The device is mounted on a 6U CubeSat with a power budget that exceeds 200 W and is in charge of transferring \dot{Q}=50 W of excess heat from a load at T₁=55 °C (e.g. an electronic component) to a radiator with area Aᵣ=600 cm² and emissivity ϵᵣ=0.9. The liquid is circulated by a magnetohydrodynamic (MHD) pump that exploits the Lorentz force

f_{L}=J×B (Eq. 1)

imposed by a magnetic field B=0.5 T applied perpendicularly to a current density field J. Permanent neodymium (N52) magnets generate the magnetic field, while the current is applied by two electrodes immersed in the liquid. The pipe has an internal diameter d and length l=0.6 m. Candidate liquid metals are listed in Table 1 and considered in the analysis.

TABLE 1
Thermophysical properties of candidate liquid metals at 25 °C and 1 atm

| | | | Specific | Thermal | Fusion | |
|---|---|---|---|---|---|---|
| | Density | Viscosity | Heat | Conductivity | Temperature | Resistivity |
| Liquid | [kg/m³] | [Pa · s/10⁻³] | [J/KgK] | [W/mK] | [°C] | [m · Ohm/10⁻⁷] |
| NaK-77 | 866 | 0.94 | 982 | 22.4 | −12.6 | 5 |
| Gallium | 6095 | 1.969 | 370 | 30.2 | 30 | 1.4 |
| Galinstan | 6440 | 2.4 | 296 | 16.5 | −19 | 2.9 |
| Mercury | 13534 | 1.5 | 139 | 8.3 | −38.9 | 9.61 |

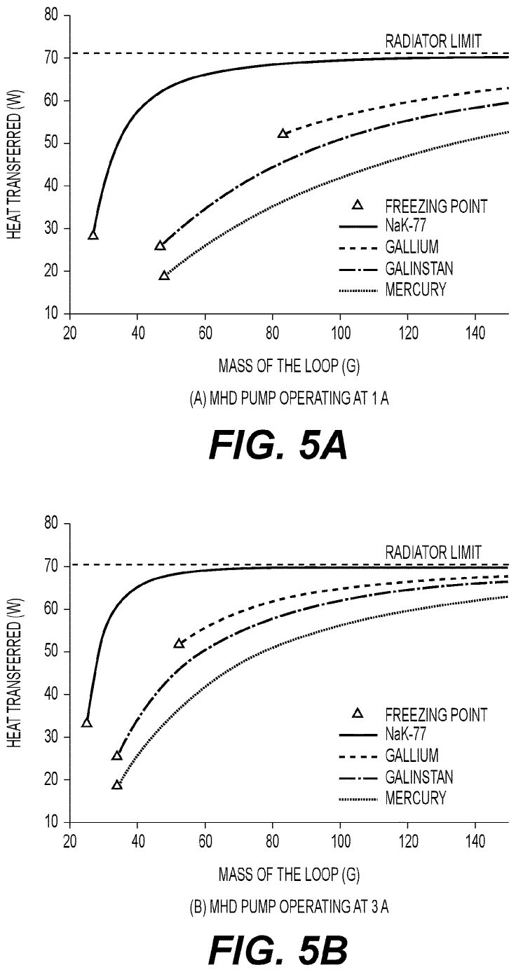

Analytical Study—The MHD pump is preliminarily configured as the brick with width d, height d, and length lₐ, as shown in FIG. 4. The electrodes responsible for inducing the current density field J are located in opposite faces of the brick so that the magnetic field B is perpendicular to J. The pressure jump induced by the pump can be defined per Equation 2.

$$Δ P = \frac{IB}{d} \qquad ( Eq . 2 )$$

In Equation 2, I is the current flowing through the electrodes. The definition J=I/(lₐd) leads to an interesting result: the shorter the electrodes (d), the higher the pressure jump.

In most cases, the liquid metal moves inside the pipe, adopting a laminar flow regime (Re<4000). The liquid volume flow rate \dot{V} can be related to the pressure drop along the pipe through the Hagen-Poiseuille law per Equation 3 where μ is the dynamic viscosity of the liquid.

$$\dot{V} = \frac{π {d}^{4} Δ P}{128 μl} \qquad ( Eq . 3 )$$

Finally, the radiator stabilizes at the equilibrium temperature per Equation 4.

$${T}_{r} = {( \frac{\dot{Q}}{σ {A}_{r} {ϵ}_{r}} )}^{\frac{1}{4}} \qquad ( Eq . 4 )$$

Because it is connected to a heat load at a constant temperature Tₗ, a physical limit is imposed on the amount of heat released. The heat transported by the loop can be determined by solving the algebraic equation per Equation 5.

$$\dot{Q} = ρ {C}_{p} \dot{V} Δ T = \frac{π ρ {C}_{p} {d}^{3} IB}{128 μl} [ {T}_{l} - {( \frac{\dot{Q}}{σ {A}_{r} {ϵ}_{r}} )}^{\frac{1}{4}} ] \qquad ( Eq . 5 )$$

In Equation, ρ, Cₚ, and μ are the density, specific heat, and viscosity of the liquid metal, respectively, and σ the Stefan-Boltzmann constant. During regulation, the system can operate based on the mass m of the heat loop per Equation 6.

$$m = \frac{π ρ {ld}^{2}}{4} + π {ρ}_{C u} lt ( t + d ) + {m}_{MHD} \qquad ( Eq . 6 )$$

In Equation 6, from left to right, the mass of the liquid metal inside the pipe, the pipe, and the MHD pump are considered. The thickness of the copper pipe t is set to 0.5 mm, while the mass of the MHD pump m_{MHD} has been estimated as 20 g. It should be noted that the mass of the system is uniquely determined by the diameter of the pipe.

The power P consumed by the system may be computed as the addition of ohmic losses that arise during the operation of the MHD pump, plus the work devoted to moving the liquid and compensating for viscous drag. The result can be expressed per Equation 7.

$$P = [ \frac{ϱ}{{l}_{a}} + \frac{π {d}^{2} {B}^{2}}{128 μl} ] {I}^{2} \qquad ( Eq . 7 )$$

In Equation 7, σ is the electrical resistivity of the conducting liquid. Regarding Eqs. 5-7, the length of the MHD pump, lₐ, does not influence the heat transferred by the system and has only a minor effect on power consumption, but it determines m_{MHD}. In other words, compact pumps are beneficial for this application. In addition, power consumption can be observed to be well below 1 W in most scenarios of interest. Additionally, heat transport appears to be strongly influenced by the area of the radiator: the larger Aᵣ, the lower the radiator temperature and the higher the heat transferred by the loop. With the liquid metals listed in Table 1 melting at between −38.90 °C and 30 °C, care should be taken to prevent the liquid from freezing and guarantee system restart.

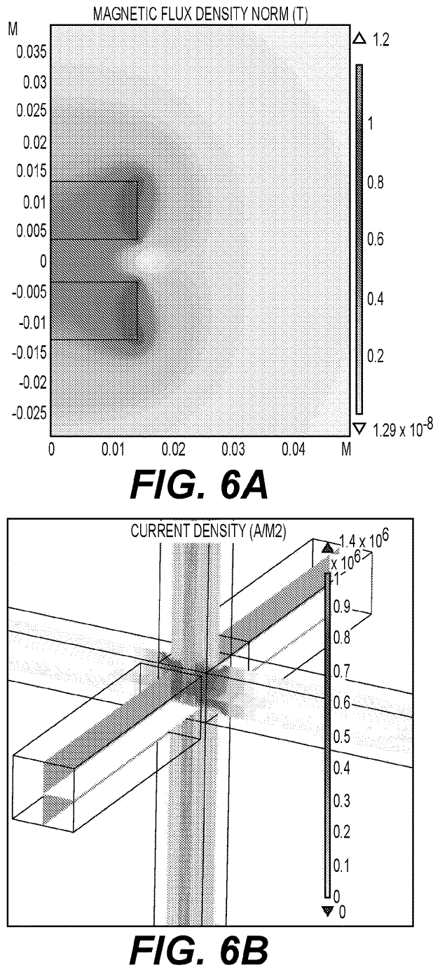

FIGS. 5A and 5B show the heat transferred by each of the liquids listed in Table 1 as a function of the overall mass of the loop. NaK-77 performs better than any other candidate thanks to its higher specific heat and lower density. However, it is also the most dangerous due to its high reactivity with water. Mercury offers the widest operating temperature range at the expense of performance, while Galinstan and Gallium lie in between. Gallium has the narrowest operating temperature range and is better suited for very high-power applications; however, it is the safest to handle, which opens interesting opportunities for hands-on education.

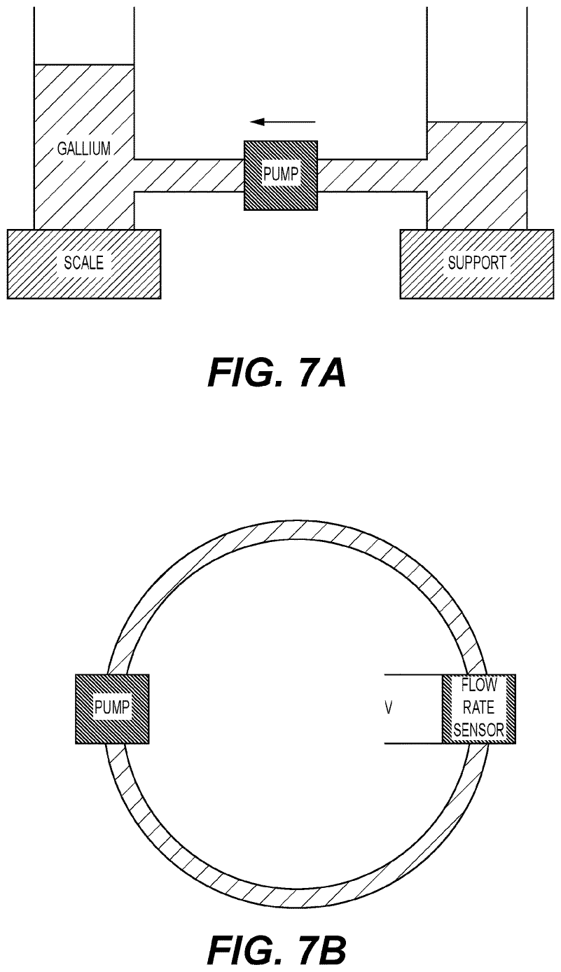

The analysis presented above may be complemented with a study of the magnetohydrodynamic environment in the vicinity of the electrodes. Preliminary results from a COMSOL simulation, reflected in FIGS. 6A and 6B indicate that (i) magnetic flux density modules of the order of 0.5 T can be readily achieved using dual magnet configurations, and (ii) the current density lines between electrodes immersed in the liquid metal flow can be made almost perfectly perpendicular to the magnetic field. Specifically, FIG. 6A shows the magnetic flux (B) field generated by a pair of opposing block magnets, and FIG. 6B shows the current density field (J) generated by a pair of opposing electrodes.

### #2—Design and Testing of a Magnetohydrodynamically Pumped Liquid Metal Cooling Loop for CubeSats

Discussion High-power SmallSats and CubeSats are faced with a limited number of thermal control technologies, many of which are not well suited to a compact form factor. This disclosure proposes a new heat transfer system designed for small spacecraft composed of a liquid metal cooling loop driven by a magnetohydrodynamic (MHD) pump. The MHD pump leverages the Lorentz force to drive the working fluid without the use of moving parts, which contributes to a low probability of failure. Analytical performance models of the MHD cooling loop are developed and validated against test data collected from a prototype system. Models indicate that the MHD loop is capable of heat transfer rates per unit mass of up to 0.75 W/g in the use case of a 6U CubeSat with a single deployable radiator, exceeding the performance of mechanically pumped fluid loops and thermal straps. Furthermore, a comparison to existing technologies shows that this low-cost system overcomes many of the practical engineering challenges associated with implementing conventional technologies such as heat pipes.

Due to their small form factor and low power usage, many CubeSat missions rely simply on conductive heat transfer directly from the internal electronics to the spacecraft structure without the use of any additional thermal management hardware. The heat is then radiated into space from the structure of the spacecraft, occasionally with the assistance of high-emissivity coatings. This architecture is sufficient for low-power systems, but as mission planners begin to design missions using hundreds or thousands of Watts, a more direct approach to thermal management must be taken.

Deployable radiators allow for increased rates of heat rejection from the spacecraft, and their use in large spacecraft is well documented. The technology has also been considered for implementation on SmallSats with a rollout deployment mechanism. This solves one aspect of the thermal management challenge. The remaining problem is transferring heat from within the satellite to the radiator effectively.

Large satellites and spacecraft use thermal straps, heat pipes, and mechanically pumped liquid coolant loops to route heat internally. Thermal strap technology transfers directly to the small satellite architecture, and many commercial examples are available. A segment of copper is used to conductively transfer heat throughout the spacecraft. The simplicity of the technology is well-suited to this expanding market. However, the heat transfer rates that can be achieved may be insufficient for high-power missions or long transmission distances. Additionally, thermal straps cannot generally be actively controlled to vary their heat transfer rate, which can be an issue when different mission phases are expected to experience significantly differing heat inputs. Thermal switching technology does offer some modulation, but full active control is not feasible.

Heat pipes offer higher heat transfer rates with a slight increase in complexity. These devices are composed of a metal casing, which contains a capillary wick and an open volume for vapor flow. A saturated liquid-vapor mixture acts as the working fluid within the device. The liquid is vaporized in the hot portion of the heat pipe, and more liquid flows up the capillary wick to replace it. The newly formed vapor flows to the condenser section of the heat pipe, where heat is extracted from the device, and the vapor condenses back into a liquid. This establishes a continuous axial flow within the heat pipe driven by capillary pressure and heat transfer. With appropriate wick design and fluid selection, heat pipes can be capable of transferring hundreds of Watts in a compact form factor. The main downside is that they can be challenging to route, expensive, cannot easily be connected to multiple heat sources, and, like thermal straps, cannot generally be actively controlled to maintain tight temperature tolerances. Loop heat pipes have also been developed for small spacecraft and offer >100 W max heat transfer rate, though they are significantly more complex and have less flight heritage than a traditional heat pipe. They also suffer from many of the practical complications of a conventional heat pipe when implemented.

Mechanically pumped fluid loops (MPFLs) promise much higher heat transfer rates, can be actively controlled, can be connected to multiple heat sources and radiators, allow simplified routing, and have spaceflight heritage. The primary issues associated with this technology are mass and volume. Additionally, mechanical pumps have a high risk of failure due to their internal mechanisms, and as such, systems must implement multiple backup pumps should the primary pump fail. This leads to a mass and volume generally incompatible with the CubeSat form factor, though there are miniature MPFL technologies in development that promise a smaller footprint. However, even the mini-MPFL is expected to have a pump mass of at least 100 g, excluding electronics, tubing, and the working fluid.

Electromagnetic pumps offer a high-reliability alternative to mechanical devices. These pumps operate on the principle that a current-carrying conductor experiences a force when placed perpendicular to a magnetic field. This allows the pump to drive a conducting fluid without the use of moving parts, which proves beneficial in many applications. Annular linear induction pumps (ALIPs) are used in systems containing high-temperature fluids that render mechanical pumps infeasible, such as nuclear devices and concentrated solar energy systems. These devices are relatively complex in their operation and rely upon a 3-phase AC power supply and a series of copper windings to generate a linearly moving magnetic field along the body of the pump. The varying magnetic field results in an induced current within the fluid, which interacts with the magnetic field to propel the liquid. Lower temperature applications that allow for direct contact between electrodes and the working fluid often opt for the simpler magnetohydrodynamic (MHD) pump. In an MHD pump, a static magnetic field is applied to a conductive fluid using either permanent or electric magnets. A DC electrical current is then applied through the fluid perpendicular to the magnetic field, propelling the working fluid through the pump. These devices have seen use in applications ranging from low-noise naval propulsion systems to nanofluidics. The simple nature of the device leads to a compact, reliable, and effective pumping system. Additionally, MHD pumps are well suited to work with high thermal conductivity and heat capacity liquids such as mercury, gallium, and other liquid metals, which can be used to efficiently transfer heat. Furthermore, appropriate applications of magnetic fields and electrical currents can be used to promote mixing and increase heat transfer rates in a liquid metal cooling loop. The combination of these features makes an MHD pump an attractive option for powering a cooling loop in small spacecraft, as depicted in FIG. 1, and while large electromagnetic pumps have been proposed for use in nuclear reactors in space, no small-scale MHD device has ever been conceived for low-temperature heat transfer applications outside of Earth's atmosphere. This disclosure introduces a small satellite cooling loop using liquid metals and an MHD pump.

In general, the simplified model of the pump flow rate and cooling loop performance developed herein is presented above with reference to Equations 1-7. However, the below section provides an analytical model of the heat transfer according to some experimental implementations.

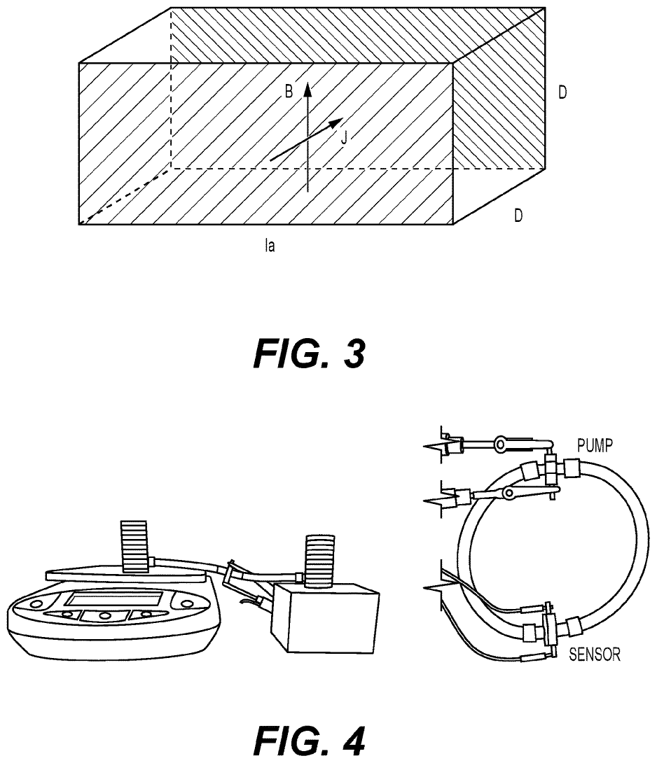

Analytical Modeling—The magnetic flux density varies with the distance between the sets of permanent magnets on either side of the pump depicted in FIGS. 3A-3B. To estimate this variation, the magnetic flux density along the symmetry axis of a rectangular block magnet can be calculated per Equation 8.

$$B = \text{} \frac{{B}_{r}}{π} [ {tan}^{- 1} ( \frac{{l}^{′} {w}^{′}}{\sqrt{4 {z}^{2} + {l}^{′ 2} + {w}^{′ 2}}} ) - {tan}^{- 1} ( \frac{{l}^{′} {w}^{′}}{2 ( {t}^{′} + z ) \sqrt{4 {( {t}^{′} + z )}^{2} + {l}^{′ 2} + {w}^{′ 2}}} ) ] \qquad ( Eq . 8 )$$

In Equation 8, Bᵣ is the residual flux density, l′ is the length of the magnet, w′ is the width of the magnet, t′ is the thickness of the magnet in the magnetization direction, and z is the distance along the centroid axis from the surface of the magnet. With this relation and equation 8, the pump output pressure can be estimated. When this is done, the magnetic flux density is assumed to be uniform and equivalent to the value calculated by Equation 9 at the midpoint between the two sets of permanent magnets.

To estimate the flow rate through the cooling loop, the flow resistance may be calculated. The flow coefficient of a fluid component may be defined as the number of gallons of water at 60 °F that can pass through a component in one minute with a one-pound-per-square-inch pressure drop. For a given flow rate and pressure drop, it can be calculated per Equation 9.

$${C}_{ν} = {\dot{V}}_{imperial} \sqrt{\frac{S . G .}{Δ {P}_{imperial}}} \qquad ( Eq . 9 )$$

In Equation 9, \dot{V}ᵢₘₚₑᵣᵢₐₗ is the volumetric flow rate in US gallons per minute, S.G. is the specific gravity of the fluid, and ΔPᵢₘₚₑᵣᵢₐₗ is the pressure drop through the component in pounds per square inch. The total pressure loss through the pump geometry has contributions from the flow through the narrow rectangular pump geometry as well as losses due to the expanding and contracting flow sections at the outlet and inlet of the pump. The pressure loss due to the uniform rectangular geometry of the pump can be calculated from Darcy's formula and the definition of hydraulic diameter per Equation 10.

$$Δ P = \frac{8 {μ ( w + H )}^{2} {l}_{p} \dot{V}}{{w}^{3} {H}^{3}} \qquad ( Eq . 10 )$$

In Equation 10, μ, w, l p, and \dot{V} are the dynamic viscosity, width of the pump cross-section, length of the internal flow path within the pump, and volumetric flow rate, respectively. The losses due to expansion and contraction are calculated per Equation 11.

$$Δ P = \frac{ρ {Kv}^{2}}{2} \qquad ( Eq . 11 )$$

In Equation 11, ρ is the fluid density, K is the resistance coefficient, and v is the mean flow velocity. For expanding flows, the resistance coefficient can be determined per Equation 12.

$${K}_{e} = {( 1 - \frac{{D}_{1}^{2}}{{D}_{2}^{2}} )}^{2} \qquad ( Eq . 12 )$$

In Equation 12, D₁ and D₂ are the hydraulic diameters of the smaller and larger flow paths, respectively. For contracting flows, the resistance coefficient is defined per Equation 13.

$${K}_{c} = 0.5 ( 1 - \frac{{D}_{1}^{2}}{{D}_{2}^{2}} ) \qquad ( Eq . 13 )$$

By combining Equations 9-13, the flow coefficient of the MHD pump and its associated pressure losses can be computed. The losses through the tubing, assuming it forms a single circular loop, are estimated using Equation 11, with Equation 14.

$${K}_{tube} = 3 ( 0.25 {f}_{T} π ( \frac{r}{d} ) + 0.5 {K}_{1} ) + {K}_{1} \qquad ( Eq . 14 )$$

In Equation 14, f_{T} is the friction factor, r/d is the bend radius of the tubing divided by its inner diameter, and K₁ is the resistance coefficient of a single 90 degree bend with equivalent bend radius. By setting the pressure developed by the pump equivalent to the pressure losses incurred in the fluid flow path and solving the equation numerically, the flow rate can be estimated. The maximum heat transfer rate achievable by the cooling loop can then be computed per Equation 15.

\dot{Q}=ρCₚ\dot{V}ΔT (Eq. 15)

In Equation 15, Cₚ is the heat capacity of the liquid metal, and ΔT=Tₗ−Tᵣ is the temperature differential between the heat load and radiator.

Experimental Setup-FIG. 4 shows a prototype pump constructed from an additively manufactured plastic frame, which is SLA printed using a Formlabs Form 3B with Clear V4 resin. Three 4.76 mm cubic nickel-plated N52 neodymium magnets were inserted into either side of the pump with a separation distance of 3.5 mm. Copper electrodes with a 3.18 mm square cross-section are placed perpendicular to the magnets with 5.5 mm between them. The electrodes directly contact the working fluid. The pump had a 2.5 mm by 4.0 mm rectangular wetted cross-section, with the shorter length being between the magnets. Hose barbs were designed into the pump to allow it to interface with 4.76 mm inner diameter (ID) flexible PVC tubing. Gallium, with a purity of 99.99%, is used as the working fluid. The pump underwent two test series to characterize its performance, one measuring the static pressure gain and the other measuring the flow rate achieved in a prototype cooling loop. A Keysight E36233A DC power supply is used in both test series.

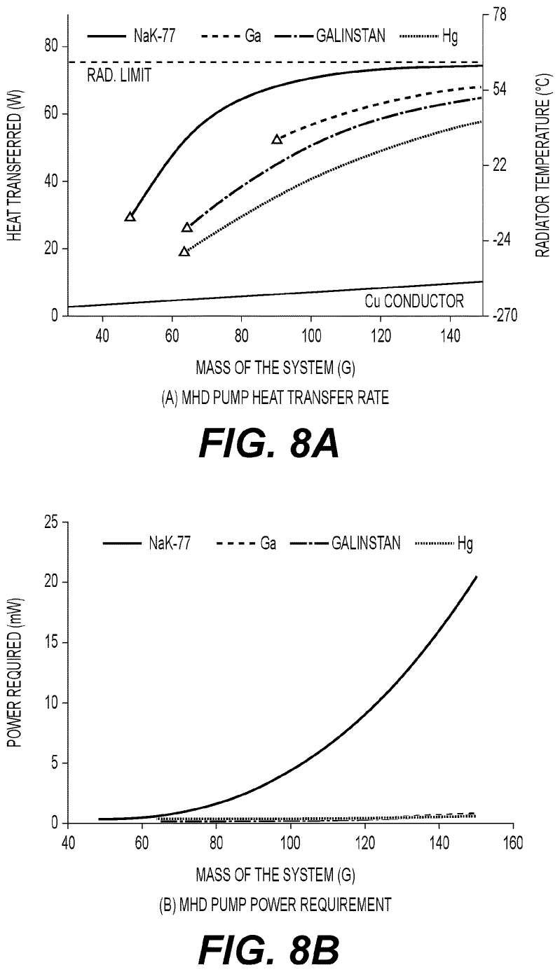

The pump was attached between two 2.54 cm inner diameter SLA printed cylindrical tanks partially filled with gallium; one is placed on a scale, as shown in FIG. 7A. When current is applied to the electrodes, gallium is pumped from the base of one tank to the other. This continued until an equilibrium was reached between the pressure output of the pump and the hydrostatic pressure difference between the two tanks. The change in mass of one of the two tanks was then recorded. The applied current was then increased by one ampere, the tanks were again allowed to come to equilibrium, and the mass was recorded again. This was repeated for a range of 1 to 15 amperes. The process was then repeated, starting at 15 amperes and decreasing in 1 ampere increments. This repetition was done to account for the effects of an advancing or receding contact line between the gallium and the tank walls, which may affect the mass of gallium within the tank. The pressure applied by the pump is then calculated by the hydrostatic pressure rise determined from the recorded masses per Equation 16.

$$P = \frac{2 {gm}_{Ga}}{π {r}_{tank}^{2}} \qquad ( Eq . 16 )$$

In Equation 16, g is the acceleration due to gravity, m_{Ga} is the mass increase of gallium in one tank, and rₜₐₙₖ is the interior radius of the cylindrical tank.

Flow rate tests are conducted using a single MHD pump connected to a magnetic flow rate sensor with geometry identical to the pump by two 15 cm sections of 4.76 mm inner diameter flexible PVC tubing, as shown in FIG. 7B. The sensor operates based on Farraday's law of induction and produces a voltage proportional to the volumetric flow rate per Equation 17.

S=C\dot{V} (Eq. 17)

In Equation 17, C is a proportionality constant related to the magnetic flux density, working fluid, and geometry within the sensor. This voltage is amplified by a factor of 1001 and measured by a LabJack T7 data acquisition system with an LJTick-InAmp amplifier. Magnets identical to those used in the pump are used to generate a magnetic field within the sensor flow cross-section. This measurement device is chosen to avoid material compatibility issues that arise when gallium is passed through many commercially available sensors. The proportionality constant, C, of the sensor is first determined by flowing gallium through it at a measured flow rate using a peristaltic pump. This is repeated at multiple flow rates. The linear coefficient relating voltage to flow rate is the slope of a line fit to the calibration data with intercept at the origin.

An electrical current is applied to the pump, and the fluid flow rate is allowed to stabilize. The voltage output from the flow sensor is then recorded. This process is repeated at multiple input currents ranging from 1 to 15 A.

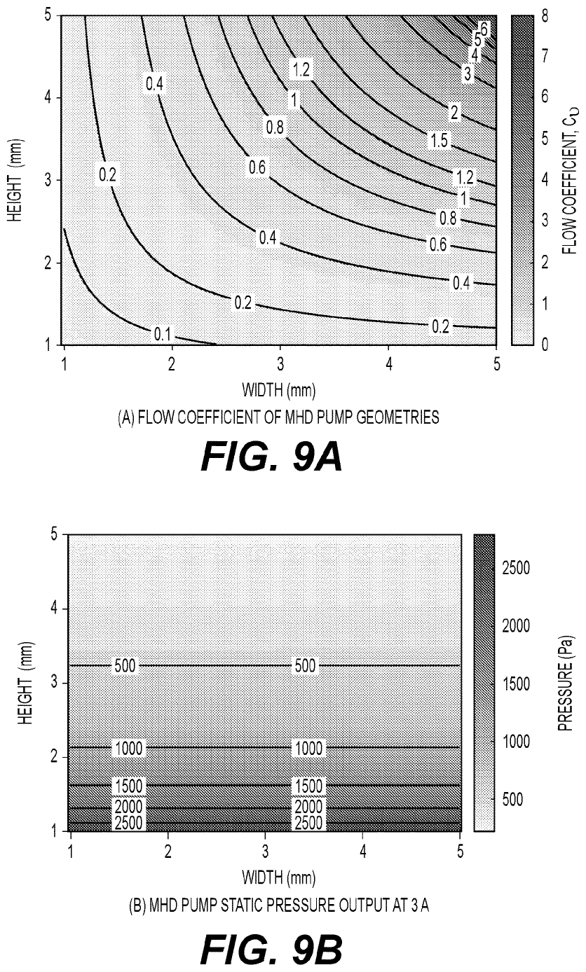

Results and Discussion-FIGS. 8A and 8B show the analytical prediction of the heat transferred by an MHD cooling loop containing each of the liquids listed in Table 1, as well as a copper heat strap as a function of the overall mass of the device. The predictions are based on the assumptions and equations developed above for a setup identical to the one shown in FIG. 1.

The physical properties of the cooling loop and radiator are listed in Table 2. These values are selected to reflect heat transport across the full length of a 6U CubeSat with a single 20 cm×30 cm deployable radiator.

TABLE 2
Geometric and physical properties of MHD loop in simulation

| Parameter | Value | | Description |
|---|---|---|---|
| l | 0.6 | m | Length of the cooling loop |
| d | 4.76 | mm | Diameter of tubing |
| B | 0.65 | T | Magnetic flux density in pump (approximated |
| | | | to be uniform) |
| lₐ | 3.18 | mm | Length of MHD pump acceleration volume |
| Aᵣ | 0.12 | m² | Surface area of the radiator |
| ϵᵣ | 0.9 | | Emissivity of radiator |
| Tₗ | 333 | K | Temperature of heat load |
| H | 2.5 | mm | Length of pump cross-section between magnets |
| w | 4.0 | mm | Width of flow cross-section between electrodes |
| I | 1 | A | Current passed through electrodes |
| t | 0.635 | mm | Thickness of copper tubing walls |

NaK-77 is capable of transferring more heat per unit mass than any other liquid metal in the MHD loop because of its higher specific heat and lower density. However, it is also the most dangerous due to its high reactivity with water, and it requires more power owing to its low density. Mercury offers the widest operating temperature range at the expense of performance, while Galinstan and Gallium lie in between. Gallium has the narrowest operating temperature range and is better suited for very high-power applications; however, it is the safest to handle and relatively inexpensive. All of the candidate MHD loops outperform heat straps in this operating range. A direct comparison with heat pipes is complicated by the highly design and temperature-dependent performance of such systems, and aluminum-cased ammonia systems are a primary example. These devices are not generally limited by their heat transfer rate.

While a thin-walled copper tube is used to route the gallium in this trade study, other materials, including flexible plastics such as PEEK, can be used. Flexible materials may prove beneficial when installing the system into a spacecraft. Copper is attractive primarily due to its material compatibility and thermal conductivity.

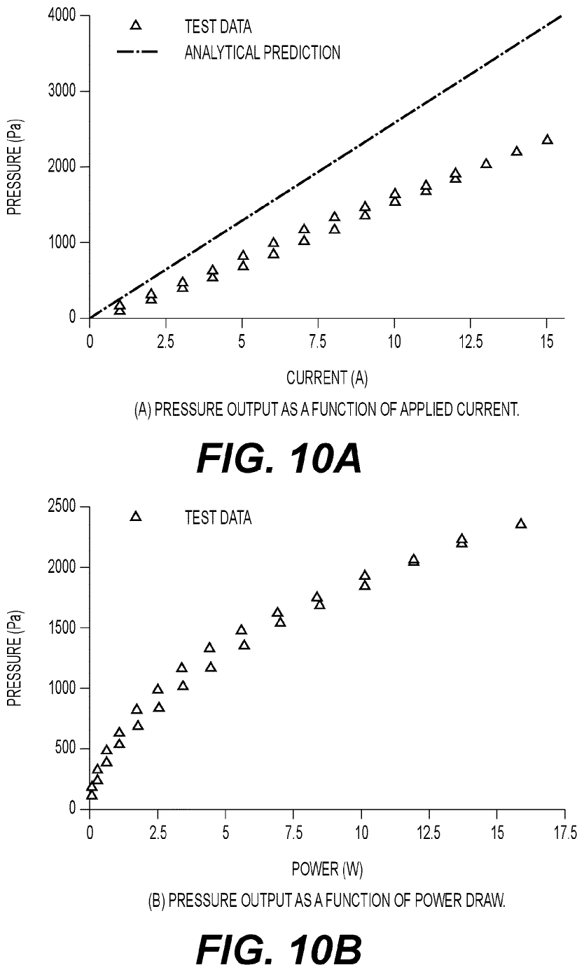

As the pump geometry affects not only the flow resistance of the pump but also the magnetic flux density within it, a trade space exists. Narrower flow passages contribute to both larger magnetic flux densities and pump output pressures while also increasing viscous losses in the flow. To elucidate theses effects, contours of the pump flow coefficient and static output pressure are developed in FIGS. 9A and 9B are based on the equations derived above. Specifically, FIG. 9A shows MHD pump geometry optimization curves for flow coefficients, while FIG. 9B shows MHD pump geometry optimization curves for static pressure output at 3 A.

As shown in FIGS. 9A and 9B, one example of a high-performing pump, would have a large width (distance between the pump electrodes). This increases the flow coefficient and has only a minor negative impact on power consumption. It would require that larger magnets be used to maintain a magnetic field across the entire cross-section, which would result in a significant increase in mass and should be considered. The ideal pump height cannot be readily determined. The greatest output pressure is attained by a pump with a small height, but this simultaneously decreases the flow coefficient. The optimal height depends on the overall flow resistance of the system as well as the electrical current applied to the electrodes.

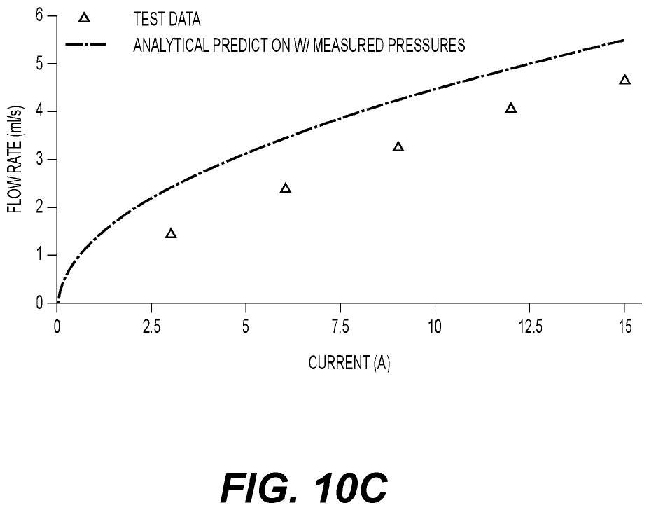

The calculated flow coefficient and flow model developed herein are validated by plotting estimated flow rates at varied electrical currents against measured data in FIG. 10C. The pressure inputs to this model are chosen to match experimental data. The estimates slightly overpredict the flow rate. This could be due to a number of factors, including simplifying assumptions made in developing the flow coefficient estimate, mild deformations of the flexible PVC tubing, gallium oxide layers forming and artificially decreasing the diameter of flow passages, and viscosity variations with temperature.

The pressure output by the system in a steady, non-flowing configuration is evaluated and plotted in FIGS. 10A and 10B. The pressure output varies linearly with the applied current, as predicted by the analytical model of the system. The analytical model overpredicts the measured output, likely due to the assumptions used in producing the model, particularly the assumptions of uniform current density and magnetic flux density. Pressure varies as the square root of the applied power as analytical models have predicted. The power required in this test is largely due to the resistance of the electrical leads connecting the pump to the DC power supply. The pump has a resistance of 1.5±0.5 mOhms between its electrodes, meaning it would draw only 22.5 mW at 15 A if power were efficiently transmitted to it. This highlights a key design consideration for this system. The flow path of current between the power processing unit and the pump itself should be minimized to reduce ohmic losses.

Measured fluid flow rates through a 30 cm loop of 4.76 mm ID tubing with a single MHD pump and a flow rate sensor with internal geometry identical to the pump are shown in 10C. The measured flow rates are approximately one order of magnitude less than those predicted by the simple analytical model. This is largely because the model does not account for head pressure losses due to flow through the flow rate sensor or the pump itself. The internal geometry of these components represents the narrowest flow passage in the cooling loop. Furthermore, the disruptions to the flow at the interface between the pump and the tubing contribute to additional losses. It should also be noted that the sensor itself accounts for roughly 30% of the viscous losses in the loop, according to analytical estimations, so a considerably higher flow rate would be expected in a loop containing only a pump and tubing.

There are a number of possible improvements to the MHD cooling loop. The performance of the pump is directly related to the magnetic flux density and electrical current density that exist within it. The electrical current density is easily increased. The primary limiting factor on the maximum allowable current will likely be the electrical system of the spacecraft that utilizes the MHD loop. Currents upward of 1 A are not always available, especially on CubeSats. As such, the implementation of a DC-DC converter capable of accepting a low-current input and developing a high-current, low-voltage output would increase the capabilities of the MHD-pumped cooling loop onboard a small spacecraft. The performance of the pump could further be improved by augmentations to the permanent magnets. The addition of an iron yoke joining the two sets of magnets could minorly increase the average magnetic flux density within the pump.

The use of larger magnets could have a similar effect. Further performance gains can be realized by placing multiple pumps in the same cooling loop. By placing two pumps in series both electrically and in the fluid system, the pressure gain is doubled. This comes at the expense of doubling the ohmic losses of the system, though this is not a substantial amount of power. An additional benefit of using two pumps is that their magnetic poles can be pointed in opposite directions, thereby reducing the total torque induced on the spacecraft by the presence of the permanent magnets in the Earth's magnetic field.

MHD-pumped cooling loops address the same thermal challenges as thermal straps, heat pipes, and MPFLs. MHD cooling loops share all of the benefits of a mechanically pumped system. Additionally, MHD systems are more reliable due to their lack of moving parts, and they are lighter weight when designed for the heat loads and length scales seen in CubeSats. For these reasons, an MHD-pumped liquid metal cooling loop is an attractive option for high-power CubeSats. Magnetohydrodynamically pumped cooling loops fill a gap in the thermal technologies market. Their low mass and volume, coupled with high heat transfer rate, make them well-suited for high-power CubeSats and small satellites. Additionally, the lack of moving parts increases the reliability of the system. This technology also offers the potential for precise thermal control due to the variable flow rate of the pump. As high-power systems become commonplace in small satellites and CubeSats, compact and adaptable technologies like this will become necessary to meet their thermal requirements.

### Configuration of Certain Implementations

The construction and arrangement of the systems and methods as shown in the various implementations are illustrative only. Although only a few implementations have been described in detail in this disclosure, many modifications are possible (e.g., variations in sizes, dimensions, structures, shapes, and proportions of the various elements, values of parameters, mounting arrangements, use of materials, colors, orientations, etc.). For example, the position of elements may be reversed or otherwise varied, and the nature or number of discrete elements or positions may be altered or varied. Accordingly, all such modifications are intended to be included within the scope of the present disclosure. The order or sequence of any process or method steps may be varied or re-sequenced according to alternative implementations. Other substitutions, modifications, changes, and omissions may be made in the design, operating conditions, and arrangement of the implementations without departing from the scope of the present disclosure. In other embodiments, the exemplary active thermal control device and method may be employed for high-power electronics, hypersonic reentry vehicles, and larger spacecraft.

The present disclosure contemplates methods, systems, and program products on any machine-readable media for accomplishing various operations. The implementations of the present disclosure may be implemented using existing computer processors, or by a special purpose computer processor for an appropriate system, incorporated for this or another purpose, or by a hardwired system. Implementations within the scope of the present disclosure include program products, including machine-readable media for carrying or having machine-executable instructions or data structures stored thereon. Such machine-readable media can be any available media that can be accessed by a computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures, and which can be accessed by a general purpose or special purpose computer or other machine with a processor.

When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general-purpose computer, special purpose computer, or special purpose processing machines to perform a certain function or group of functions.

Although the figures show a specific order of method steps, the order of the steps may differ from what is depicted. Also, two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule-based logic and other logic to accomplish the various connection steps, processing steps, comparison steps and decision steps.

It is to be understood that the methods and systems are not limited to specific synthetic methods, specific components, or to particular compositions. It is also to be understood that the terminology used herein is for the purpose of describing particular implementations only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another implementation includes from the one particular value and/or to the other particular value. Similarly, when values are expressed as approximations, by use of the antecedent “about,” it will be understood that the particular value forms another implementation. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not. Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal implementation. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application, including, but not limited to, steps in disclosed methods. Thus, if there are a variety of additional steps that can be performed it is understood that each of these additional steps can be performed with any specific implementation or combination of implementations of the disclosed methods.

The following patents, applications and publications as listed below and throughout this document are hereby incorporated by reference in their entirety herein.

### REFERENCE LIST

[1] Kulu, E., “Nanosatellite Launch Forecasts-Track Record and Latest Prediction,” AIAA Small Satellite Conference, Logan, UT, 2022, pp. 1-17. URL https://digitalcommons.usu.edu/cgi/viewcontent.cgi?article=5166&context=smallsat.
[2] Bouwmeester, J., and Guo, J., “Survey of worldwide pico- and nanosatellite missions, distributions and subsystem technology,” Acta Astronautica, Vol. 67, No. 7, 2010, pp. 854-862. https://doi.org/10.1016/j.actaastro.2010.06.004.
[3] Sternberg, D., Essmiller, J., Colley, C., Klesh, A., and Krajewski, J., “Attitude Control System for the Mars Cube One Spacecraft,” 2019 IEEE Aerospace Conference, 2019, pp. 1-10. https://doi.org/10.1109/AERO.2019.8741816.
[4] Agarwal, R., Oh, B., Fitzpatrick, D., Buynovskiy, A., Lowe, S., Lisy, C., Kriezis, A., Lan, B., Lee, Z., Thomas, A., Wallace, B., Costantino, E., Miner, G., Thayer, J., D'Amico, S., Lemmer, K., Lohmeyer, W., and Palo, S., “Coordinating Development of the SWARM-EX CubeSat Swarm Across Multiple Institutions,” AIAA Small Satellite Conference, Logan, UT, 2021, pp. 1-12. URL https://digitalcommons.usu.edu/cgi/viewcontent.cgi?article-5104&context=smallsat.
[5] Hengeveld, D., Moulton, J., Lockyer, S., Taft, B., and Kwas, A., “Enabling High-Power SmallSats with Advanced Thermal Management,” AIAA Small Satellite Conference, Logan, UT, 2019. URL https://digitalcommons.usu.edu/smallsat/2019/all2019/292.
[6] Hengeveld, D., Moulton, J., Wilson, M., Taft, B., and Kwas, A., “Thermal Design Considerations for Future High-Power Small Satellites,” 48th International Conference on Environmental Systems, Albuquerque, NM, 2018. URL http://hdl.handle.net/2346/74080.
[7] NASA, “Small Spacecraft Technology State-of-the-Art,” Tech. Rep. NASA/TP-2022-0018058, NASA, Ames Research Center, Moffett Field, California, January 2023. URL https://www.nasa.gov/smallsat-institute/sst-soa/.
[8] Miesner, S., Wolk, K., Furst, B., Daimaru, T., Sunada, E., Roberts, S., Bellardo, J., and Kuo, J., “Thermal Testing of an AMDROHP (Additively Manufactured Deployable Radiator Oscillating Heat Pipes) for Use in High-Powered CubeSats,” ASME 2023 International Mechanical Engineering Congress and Exposition, 2024. https://doi.org/10.1115/IMECE2023-114249.
[9] Gilmore, D., Spacecraft thermal control handbook. 1: Fundamental technologies, 2nd ed., Aerospace Press [u.a.], El Segundo, Calif, 2002.
[10] Wertz, J. R., Everett, D. F., and Puschell, J. J. (eds.), Space mission engineering: the new SMAD, No. v. 28 in Space technology library, Microcosm Press: Sold and distributed worldwide by Microcosm Astronautics Books, Hawthorne, CA, 2011.
[11] Yendler, B., Meginnis, A., and Reif, A., “Thermal Management for High Power Cubesats,” AIAA Small Satellite Conference, Logan, UT, 2020. URL https://digitalcommons.usu.edu/smallsat/2020/all2020/41.
[12] “Thermal Management Technologies Thermal Strap Catalog,” Product Catalog, Thermal Management Technologies, Logan, UT, January 2020. URL https://www.tmt-ipe.com/thermal-components.
[13] “Thermal Straps,” Product Catalog SDL/11-224 Rev. F, Space Dynamics Laboratory, Logan, UT, 2024. URL https://www.sdl.usu.edu/downloads/brochures/thermal-straps.pdf.
[14] Du, T., Xiong, Z., Delgado, L., Liao, W., Peoples, J., Kantharaj, R., Chowdhury, P. R., Marconnet, A., and Ruan, X., “Wide range continuously tunable and fast thermal switching based on compressible graphene composite foams,” Nature Communications, Vol. 12, No. 1, 2021, p. 4915. https://doi.org/10.1038/s41467-021-25083-8.
[15] Brouwer, H., Groot, Z., Guo, J., and Gerner, H. J. v., “Solving the Thermal Challenge in Power-Dense CubeSats with Water Heat Pipes,” AIAA Small Satellite Conference, Logan, UT, 2017. URL https://digitalcommons.usu.edu/smallsat/2017/TS7AdvTech2/4.
[16] Brennan, P., Kroliczek, E., Jen, H., and McIntosh, R., “Axially grooved heat pipes-1976,” 12th Thermophysics Conference, American Institute of Aeronautics and Astronautics, Albuquerque, NM, 1977. https://doi.org/10.2514/6.1977-747
[17] Brennan, P. J., and Kroliczek, E. J., “Heat Pipe Design Handbook: Volume I,” Tech. Rep. NASA-CR-163661, NASA, June 1979. URL https://ntrs.nasa.gov/citations/19810065690, nTRS Author Affiliations: B and K Engineering, Inc. NTRS Document ID: 19810065690 NTRS Research Center: Goddard Space Flight Center (GSFC).
[18] Richard, B., Anderson, W. G., and Crawmer, J., “Development of a 3D Printed Loop Heat Pipe,” 2019 35th Semiconductor Thermal Measurement, Modeling and Management Symposium (SEMI-THERM), San Jose, CA, 2019, pp. 58-60. URL https://ieeexplore.ieee.org/document/9165293.
[19] Thurman, R. L., and McCall, F. C., “Design and Control of Space Station Freedom U.S. Laboratory Active Thermal Control System,” SAE Transactions, Vol. 101, 1992, pp. 322-346. https://doi.org/https://doi.org/10.4271/921109.
[20] van Es, J., Pauw, A., van den Berg, R., and van Kleef, A., “Micro-pumped cooling loop to standardize micro-sat thermal control,” 69th International Astronautical Congress, Bremen, Germany, 2018. URL https://iafastro.directory/iac/archive/browse/IAC-18/C2/7/42197/.
[21] van Es, J., Ganzeboom, T., van den Berg, T. H., Van Vliet, A., Brouwer, H. S. B., and Elvik, S., “Mini Mechanically Pumped Loop Modelling, Design and Tests for standardized cubesat thermal control,” 50th International Conference on Environmental Systems, Virtual Event, 2021. URL https://hdl.handle.net/2346/87057.
[22] Lorenzin, N., and Abánades, A., “A Review on the Application of Liquid Metals as Heat Transfer Fluid in Concentrated Solar Power Technologies,” International Journal of Hydrogen Energy, Vol. 41, 2016, pp. 6990-6995. https://doi.org/10.1016/j.ijhydene.2016.01.030.
[23] Geng, S. M., and Reid, T. V., “Two-Step Multi-Physics Analysis of an Annular Linear Induction Pump for Fission Power Systems,” 14th International Energy Conversion Engineering Conference, Salt Lake City, UT, 2016. URL https://ntrs.nasa.gov/citations/20160014541, NTRS Document ID: 20160014541 NTRS Research Center: Glenn Research Center (GRC).
[24] Sharma, P., Sivakumar, L. S., Prasad, R. R., Saxena, D. K., Kumar, V. A. S., Nashine, B. K., Noushad, I. B., Rajan, K. K., and Kalyanasundaram, P., “Design, Development and Testing of a Large Capacity Annular Linear Induction Pump,” Energy Procedia, Vol. 7, 2011, pp. 622-629. https://doi.org/10.1016/j.egypro.2011.06.083.
[25] Nishigaki, K., Sha, C., Takeda, M., Peng, Y., Zhou, K., Yang, A., Suyama, D., Qing, Q. J., Yan, L., Kiyoshi, T., and Wada, H., “Elementary study on superconducting electromagnetic ships with helical insulation wall,” Cryogenics, Vol. 40, 2000, pp. 353-359. https://doi.org/10.1016/S0011-2275(00)00049-7.
[26] Al-Habahbeh, O. M., Al-Saqqa, M., Safi, M., and Abo Khater, T., “Review of magnetohydrodynamic pump applications,” Alexandria Engineering Journal, Vol. 55, No. 2, 2016, pp. 1347-1358. https://doi.org/10.1016/j.aej.2016.03.001.
[27] Heinzel, A., Hering, W., Konys, J., Marocco, L., Litfin, K., Müller, G., Pacio, J., Schroer, C., Stieglitz, R., Stoppel, L., Weisenburger, A., and Wetzel, T., “Liquid Metals as Efficient High-Temperature Heat-Transport Fluids,” Energy Technology, Vol. 5, 2017, pp. 1026-1036. https://doi.org/10.1002/ente.201600721.
[28] Modestov, M., Kolemen, E., Fisher, A. E., and Hvasta, M. G., “Electromagnetic control of heat transport within a rectangular channel filled with flowing liquid metal,” Nuclear Fusion, Vol. 58, 2018. https://doi.org/10.1088/1741-4326/aa8bf4.
[29] Maidana, C. O., “Design of Annular Linear Induction Pumps for Space Nuclear Reactors,” Thermo-Magnetic Systems for Space Nuclear Reactors: An Introduction, edited by C. O. Maidana, SpringerBriefs in Applied Sciences and Technology, Springer International Publishing, Cham, 2014, pp. 33-47. https://doi.org/10.1007/978-3-319-09030-6_5.
[30] Patel, H. D., “Use of Permanent Magnets to Improve the Seismic Behavior of Light-Framed Structures,” Ph.D. thesis, Virginia Tech, May 2005. URL http://hdl.handle.net/10919/42707.
[31] Crane Co., Flow of Fluids Through Valves, Fittings, and Pipe, Vervante, 1988.
[32] Sutera, S. P., and Skalak, R., “The History of Poiseuille's Law,” Annual Review of Fluid Mechanics, Vol. 25, No. 1, 1993, pp. 1-20. https://doi_org/10.1146/annurev.f1.25 010193.000245.
[33] Aundal, K. T., “Permanent magnet flowmeter with noncircular sensing passage,”, August 2005. URL https://patents.google.com/patent/U.S. Pat. No. 6,931,943B1/en.
[34] EGO, “Safety Data Sheet-Thermostats filled with Potassium-sodium alloy (NaK),” Safety Data Sheet V1, EGO, April 2021. URL https://www.gev. online.com/resources/Artikelinfo/Mzc1MjQ2X1NlY0Rhc2hfNzAxNTNfRU5VX1VOMzU0M19XUOZSRUk=.pdf.
[35] Aldrich, “Gallium Safety Data Sheet V6.6,” Safety Data Sheet Aldrich—203319, Sigma-Aldrich, September 2021. URL https://www.sigmaaldrich.com/US/en/sds/aldrich/203319.
[36] Gerner, H. J. v., Brouwer, H., Groot, Z. d., and Guo, J., “Water-filled heat pipes for CubeSat thermal control,” IOP Conference Series: Materials Science and Engineering, Vol. 1139, No. 1, 2021, p. 012003. https://doi.org/10.1088/1757-899X/1139/1/012003.
[37] Saba Z. Shaik, Oliver Jia-Richards, and Paulo C. Lozano, “Characterization of a Single-Polarity Electrospray Propulsion System,” 37th International Electric Propulsion Conference, Cambridge, MA, 2022. URL https://hdl.handle.net/1721.1/145401.
[38] McAfee, R., Fish, M., Baker, D., Gess, J., and Boteler, L., “Compatibility Analysis of Liquid Gallium and Common Packaging Metals for Application in Electronic Component Thermal Management,” InterSociety Conference on Thermal and Thermomechanical Phenomena in Electronic Systems, ITHERM, Vol. 2020-July 2020, pp. 1276-1281. https://doi.org/10.1109/ITherm45881.2020.9190557.
[39] Andreas Urban, “Permanent magnet with yoke for generating a strong magnetic field for educational purposes,” July 2009. URL https://patents.google.com/patent/DE202009005692U1/en, number: DE202009005692U1.
[40] Benthem, R. C. v., van Gerner, H. J., Es, J. v., Vliet, A. v., Put, P. v., Elst, J., and Schwaller, D., “Valve-less Mechanically Pumped Fluid Loop (MPFL) using East andWest Panels of a Large Telecommunication Satellite as Radiator,” 45th International Conference on Environmental Systems, Bellevue, WA, 2015. URL http://hdl.handle.net/2346/64354.

1. A system comprising:
a heat-transfer conduit having a first end and a second end opposite the first end that forms a circulating loop, the conduit defining a flow channel comprising a liquid metal;
a first heat exchanger to couple to a thermal load disposed on the first end of the conduit loop and configured to transfer heat from a connected thermal load into the liquid metal of the conduit;
a second heat exchanger to couple to a thermal sink, the second heat exchanger being disposed on the second end of the conduit and configured to transfer heat from the liquid metal to the thermal sink;
a magnetohydrodynamic (MHD) pump assembly coupled to a portion of the conduit, the magnetohydrodynamic pump assembly comprising (i) at least one electrode configured to generate an electric current density in a first direction perpendicular to a longitudinal axis of the portion of the conduit loop, (ii) at least one magnet configured to generate a magnetic flux density in a second direction perpendicular to both the first direction and the longitudinal axis of the portion of the conduit; and
a controller coupled to the magnetohydrodynamic pump assembly and configured to adjust an electric current applied to the at least one electrode to vary the intensity of the electric current density in the first direction, which varies a flow rate of the liquid metal
wherein a resulting Lorentz force between the at least one electrode and the at least one magnet induces motion of the liquid metal in a third direction parallel to the longitudinal axis of the portion of the conduit loop.

2. The system of claim 1, wherein the at least one electrode includes a first electrode on a first side of the conduit loop and a second electrode on a second side of the conduit loop opposite of the first side, the first and second electrodes being separated by a first distance.

3. The system of claim 2, wherein the first and second electrode are in contact with the liquid metal.

4. The system of claim 1, wherein the at least one magnet includes a first set of magnets on a third side of the conduit loop and a second set of magnets on a fourth side of the conduit loop opposite of the third side, the first and second set of magnets being separated by a second distance.

5. The system of claim 4, wherein the first set of magnets includes 3 neodymium magnets arranged in series in the magnetohydrodynamic pump along the third side of the conduit loop.

6. The system of claim 1, wherein the at least one magnet is a neodymium magnet.

7. The system of claim 1, wherein the liquid metal is one of gallium, Galinstan, mercury, or NaK-77.

8. The system of claim 1, further comprising a controller operatively coupled to the magnetohydrodynamic pump, the controller being configured to operate the magnetohydrodynamic pump to increase or decrease a flowrate of the liquid metal therethrough.

9. The system of claim 8, wherein the controller is configured to operate the magnetohydrodynamic pump based on a Lorentz volume force or static pressure of the liquid metal.

10. The system of claim 1, wherein the magnetohydrodynamic pump is configured to transfer a pre-defined heat flux from a subsystem of a satellite to a deployable radiator.

11. The system of claim 1, the system further comprising a power supply, wherein the electric current density generated in the at least on electrode is a DC current source from the power supply.

12. The system of claim 1, wherein the electric current density generated in the at least one electrode is a DC current source generated by the controller.

13. The system of claim 1, wherein the magnetohydrodynamic pump is a first magnetohydrodynamic pump coupled to a first portion of the conduit loop, the system further comprising a second magnetohydrodynamic pump coupled to a second portion of the conduit loop, each of the first and second magnetohydrodynamic pumps configured to apply a Lorentz force to induce motion of the liquid metal.

14. A satellite or spacecraft comprising a system, the system comprising:
a heat-transfer conduit having a first end and a second end opposite the first end that forms a circulating loop, the conduit defining a flow channel comprising a liquid metal;
a first heat exchanger to couple to a thermal load disposed on the first end of the conduit loop and configured to transfer heat from a connected thermal load into the liquid metal of the conduit;
a second heat exchanger to couple to a thermal sink, the second heat exchanger being disposed on the second end of the conduit and configured to transfer heat from the liquid metal to the thermal sink;
a magnetohydrodynamic pump assembly coupled to a portion of the conduit, the magnetohydrodynamic pump assembly comprising (i) at least one electrode configured to generate an electric current density in a first direction perpendicular to a longitudinal axis of the portion of the conduit loop, (ii) at least one magnet configured to generate a magnetic flux density in a second direction perpendicular to both the first direction and the longitudinal axis of the portion of the conduit; and
a controller coupled to magnetohydrodynamic pump assembly and configured to adjust an electric current applied to the at least one electrode to vary the intensity of the electric current density in the first direction, which varies a flow rate of the liquid metal
wherein a resulting Lorentz force between the at least one electrode and the at least one magnet induces motion of the liquid metal in a third direction parallel to the longitudinal axis of the portion of the conduit loop.

15. A method of transferring heat, the method comprising:
providing a heat-transfer conduit having a first end and a second end opposite the first end that forms a circulating loop, the conduit defining a flow channel comprising a liquid metal, wherein a first heat exchanger to couple to a thermal load is disposed on the first end of the conduit loop and configured to transfer heat from a connected thermal load into the liquid metal of the conduit, wherein a second heat exchanger to couple to a thermal sink is disposed on the second end of the conduit and configured to transfer heat from the liquid metal to the thermal sink;
providing a magnetohydrodynamic pump assembly coupled to a portion of the conduit, the magnetohydrodynamic pump assembly comprising at least one electrode on a first side of the portion of the conduit and at least one magnet on a second side of the portion of the conduit;
applying a current to the at least one electrode to generate an electric current density in a first direction perpendicular to the longitudinal axis of the conduit;
generating a magnetic flux density in a second direction perpendicular to both the first direction and the longitudinal axis of the conduit;
inducing motion of the liquid metal in a longitudinal direction along the conduit via the resulting Lorentz force generated by the electric current density and the magnetic flux density.

16. The method of claim 15, further comprising:
providing a controller coupled to the magnetohydrodynamic (MHD) pump assembly; and adjusting an electric current applied to the at least one electrode to vary the intensity of the electric current density in the first direction.

17. The method of claim 16, wherein adjusting the electric current applied to the at least one electrode adjusts the flow rate of the liquid metal through the conduit.

18. The method of claim 16, further comprising:
providing a power supply coupled to the at least one electrode and the controller; and
generating a DC current to the at least one electrode to generate the electric current density.

19. The method of claim 15, wherein the thermal load is a heat-generating device of a device, and the thermal sink is a radiator configured to dissipate the heat into an external environment.

20. The method of claim 15, wherein the thermal load comprises a plurality of heat-generating devices of a satellite or spacecraft system, wherein the thermal sink is a deployable radiator of the satellite or spacecraft system, the magnetohydrodynamic (MHD) pump assembly being powered by a power supply of the satellite or spacecraft system.
